(19) United States
(12) Patent Application Publication
(10) Pub. No.: US 2002/0004284 A1
(43) Pub. Date: Jan. 10, 2002

(54) METHOD FOR FORMING A SHALLOW TRENCH ISOLATION STRUCTURE INCLUDING A DUMMY PATTERN IN THE WIDER TRENCH

(76) Inventor: TERRY CHEN, TAIPEI HSIEN (TW)

Correspondence Address: OPPENHEIMER WOLFF & DONNELLY, P. O. BOX 10356, PALO ALTO, CA, 94304, US

(21) Appl. No.: 09/187,062

(22) Filed: Nov. 5, 1998

(30) Foreign Application Priority Data
Aug. 25, 1998 (TW) 87113977

(51) Int. Cl. H01L 21/76

(52) U.S. Cl. 438/427; 438/424; 438/435; 438/437

(57) ABSTRACT

A method of forming a shallow trench isolation structure is provided. A substrate having a pad oxide layer and a first insulating layer formed thereon is provided. A first trench with a small size and a second trench with a large size are formed in the substrate. A first dielectric layer and a second insulating layer are formed on the substrate sequentially. The second insulating layer is defined to form a dummy pattern to occupy a part of the second trench. A second dielectric layer is formed on the first dielectric layer and to fill into the remaining space of the second trench. A CMP process is performed to complete the shallow trench isolation trench structure.

### BACKGROUND OF THE INVENTION

1. Field of the Invention

The invention relates in general to the fabrication of semiconductor integrated circuits (ICs), and more particularly to a chemical mechanical polishing (CMP) applied in forming the semiconductor integrated circuits.

2. Description of the Related Art

CMP is now a technique ideal for applying in global planarization in very large scale integration (VLSI) and even in ultra large scale integration (ULSI). Moreover, CMP is likely to be the only reliable technique as the feature size of the integrated circuit (IC) is highly reduced. Therefore, it is of great interest to develop and improve the CMP technique in order to cut down the cost.

As the IC devices are continuously sized down to a line width of 0.25 μm or even 0.18 μm (deep sub-half micron), using CMP to planarize the wafer surface, especially to planarize the oxide layer on the surface of the shallow trench, becomes more important. To prevent the dishing effect occurring at the surface of a larger trench during CMP process and to obtain a superior CMP uniformity, a reverse tone active mask was proposed, incorporated with an etching back process.

Typically, the active regions and the shallow trenches between these active regions both have variable sizes. FIG. 1A-1E are cross-sectional views showing the process steps for forming a shallow trench isolation using CMP. Referring to FIG. 1A, on a substrate 10, a pad oxide layer 15 and a silicon nitride layer 16 are deposited successively. By photolithography, the substrate 10, the pad oxide layer 15 and the silicon nitride layer 16 are anisotropically etched to form shallow trenches 14 and to define active regions 12. The sizes of the shallow trenched 14 are different since the sizes of the active regions 12 are varied.

In FIG. 1B, an oxide layer 18 is deposited by atmosphere pressure chemical deposition (APCVD) on the substrate 10 to fill the shallow trenches 14. However, due to the step coverage properties of the oxide layer 18, the deposited oxide layer 18 has an uneven surface and a rounded shaped. A photoresist layer is coated on the surface of the oxide layer 16 and patterned to form a reverse active mask 20 by photolithography. The reverse active mask 20 covers the oxide layer 18 on the shallow trenches 14 and is complementary to the active regions 12. If a misalignment occurs while forming the reverse active mask, the oxide layer 18 may cover more oxide layer 18 other than the position on the shallow trenches 14 during the formation of the reverse active mask. On the other hand, the oxide layer 18 covered by the reverse active mask 20 may only cover a part of the shallow trenches 14.

In FIG. 1C, the exposed oxide layer 18 is etched until the silicon nitride layer 16 is exposed so that only a part of the silicon oxide layer 18, denoted as the silicon oxide layer 18a, is formed after removing the reverse active mask 20. As shown in FIG. 1D, it is seen that the remaining silicon oxide layer 18a does not fully cover the shallow trenches 14 at one side of the shallow trenches 14. Recesses 22 are thus formed. At the other sides of the shallow trenches 14, a photo-overlap 24 is formed.

In FIG. 1E, the reverse active mask 20 is removed. The portion of the oxide layer 18a higher than the shallow trenched 14 is polished by CMP until the surface of the silicon nitride layer 16 is exposed. Therefore, the silicon nitride layer 16 and the silicon oxide layer 18a have a same surface level. However, the profile of the silicon oxide layer 18a formed by APCVD is rather rounded. Thus, it is difficult to effectively plaranize the silicon oxide layer 18a by CMP. In addition, with the formation of the recesses 22, it is obviously shown in the figure that the shallow trenches 14 are not completely filled with the silicon oxide layer 18a. The undesired recesses 22 may cause kink effect and consequent short circuit or leakage current which therefore influence the yield. Since silicon nitride is harder than silicon oxide, the top surface of the silicon oxide layer 18a has micro-scratches during CMP.

As a result, it is important to overcome the problems coming after the formation of the cavities due to the misalignment of the reverse active mask during the process of CMP, especially, while nowadays the line width is decreasing.

### SUMMARY OF THE INVENTION

It is therefore an object of the invention to provide an improved and simplified process of forming a shallow trench isolation structure to prevent the formation of recesses or micro- scratches being formed while a CMP process is performed.

It is another object of the invention to use a dummy pattern to prevent the dishing effect occurring at the surface of a larger trench during CMP process and to obtain a superior CMP uniformity.

The invention achieves the above-identified objects by providing a method for forming a shallow trench isolation structure. A substrate having a pad oxide layer and a first insulating layer formed thereon is provided. A first trench with a small size and a second trench with a large size are formed in the substrate. A first dielectric layer and a second insulating layer are formed on the substrate sequentially. The second insulating layer is defined to form a dummy pattern occupying a part of the second trench. A second dielectric layer is formed on the first dielectric layer and to fill into the remained space of the second trench. A CMP process is performed to form a shallow trench isolation trench structure.

### BRIEF DESCRIPTION OF THE DRAWINGS

Other objects, features, and advantages of the invention will become apparent from the following detailed description of the preferred but non-limiting embodiments. The description is made with reference to the accompanying drawings in which:

FIG. 1A-1E are cross-sectional views showing a conventional process of forming a conventional shallow isolation trench using a reverse active mask; and

FIG. 2A-2E are cross-sectional views showing the process steps for forming a shallow isolation trench structure according to a preferred embodiment of the invention.

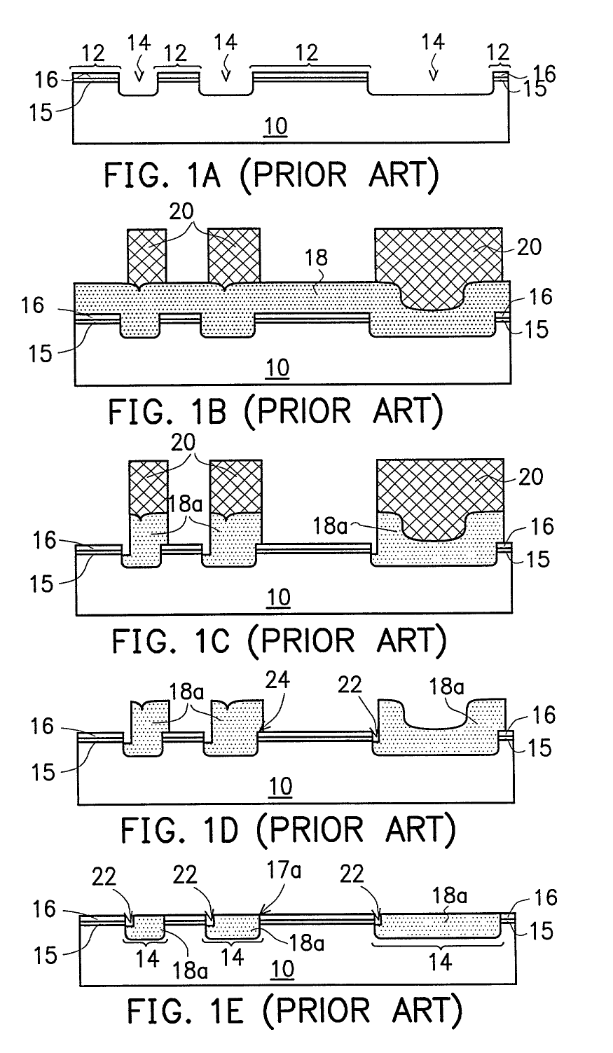

### DESCRIPTION OF THE PREFERRED EMBODIMENT

The invention provides a process for forming STI incorporating CMP technique. This process prevents the formation of recesses in the shallow trenches due to the misalignment of the reverse active mask to avoid short circuit or leakage current.

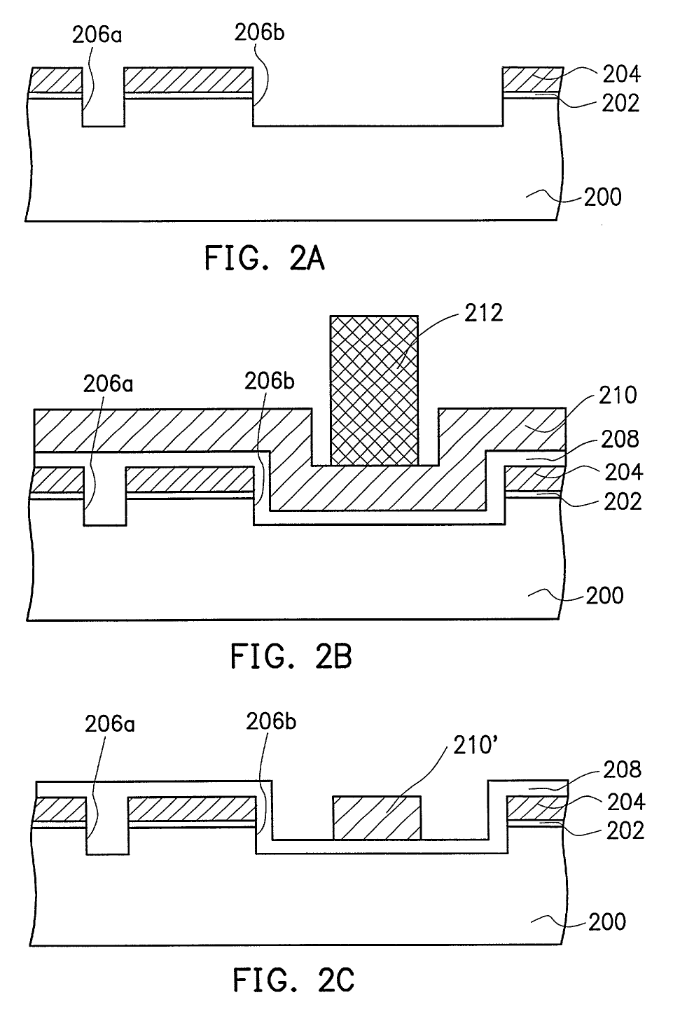

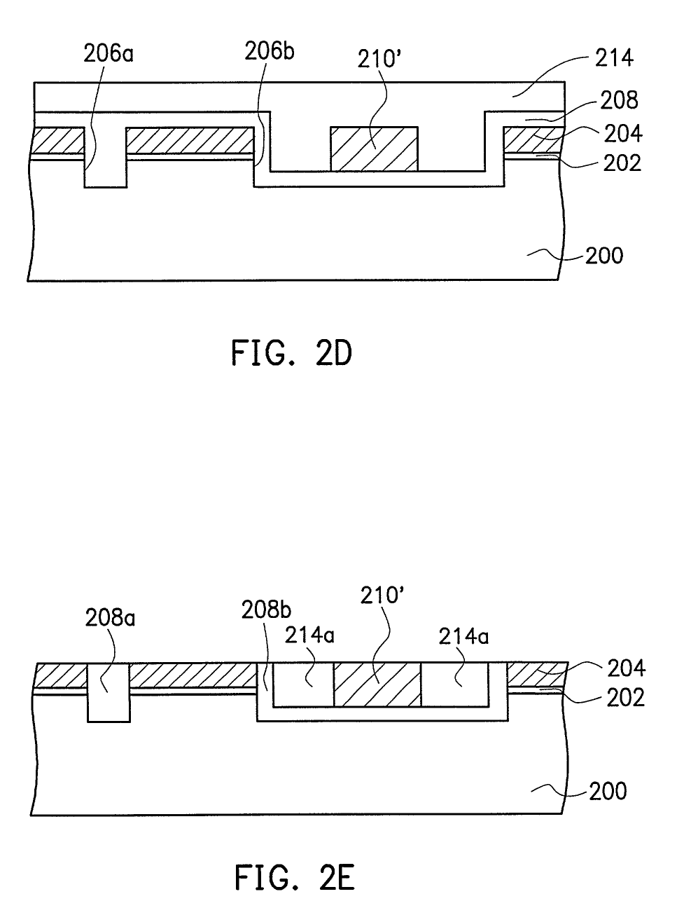

Referring to FIG. 2A, a substrate 200 is provided. A pad oxide layer 202 and a first insulating layer 204, such as a silicon nitride layer (SiNₓ) or a silicon-oxy-nitride layer (SiOₓN_{y}), are formed on the substrate 200. A photolithography and etching process is performed to removed a part of the first insulating layer 204, a part of the pad oxide layer 202 and a part of the substrate 200. A first trench 206a with a small size and a second trench 206b with a large size are thus formed in the substrate 200.

In FIG. 2B, a first dielectric layer 208 and a second insulating layer 210 are sequentially formed on the structure described above. The small first trench 206a is filled while forming the first dielectric layer 208. Since the size of the second trench 206b is large, the first dielectric layer 208 and the second insulating layer 210 are formed along the profile of the second trench 206b and there is still a space free of the first dielectric layer 208 within the second trench 206b. The second insulating layer 210 comprises silicon nitride, silicon-oxy-nitride or other similar materials. The surface level of the second insulating layer 210 in the position of the second trench 206b is as same as the surface level of the first insulating layer 204. The first dielectric layer 206 comprises silicon oxide or other materials having a large etching selectivity to the second insulating layer 210.

In FIG. 2B, a photoresist layer 212 is formed to cover a part of the second insulating layer 210 at the position on the second trench 206b. It is noticed that a distance between the side-wall of the photoresist layer 212 and the side-wall of the second trench 206b must be larger than 0.5 μm from a resolution criterion in photolithography of an existent optical system. If the resolution can be improved, the distance between the photoresist layer 212 and the side-wall of the second trench 206b also can be shortened.

Referring to FIG. 2C, a part of the second insulating layer 210 uncovered by the photoresist layer 212 is removed until the first dielectric layer 208 being exposed. This step forms a dummy pattern 210' in the large second trench 206b. The photoresist layer 212 is removed after forming the dummy pattern 210'.

In FIG. 2D, a second dielectric layer 214 is formed, for example, by chemical vapor deposition (CVD) on the first dielectric layer 208 and the dummy pattern 210'. The second dielectric layer 214 comprises silicon oxide or other materials having a large etching selectivity to the second insulating layer 210.

As shown in FIG. 2E, a portion of the second dielectric layer 214 and a portion of the first dielectric layer 208 on the first insulating 204 are removed using CMP with the first insulating layer 204 and the dummy pattern 210' as s stop layer. A first dielectric plug 208a is remained on the first trench 206a, and a second dielectric plug 214a and a portion of the first dielectric layer 208b are remained in a space between the second trench 206b and the dummy pattern 210'. The first insulating layer 204 and the dummy pattern 210' used as s stop layer are removed, for example, by wet etching in a follow-up step to expose the top surface of the substrate 200 to complete the shallow trench structure.

Since a part of the large second trench is occupied by the dummy pattern 210', no broad region of dielectric material filled in the second trench needs to be removed while a CMP process is performed. The dishing effect and micro-scratches occurring at the top surface of a larger trench during CMP by a prior technique are prevented.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for forming a shallow trench isolation structure, comprising the steps of:
providing a substrate having a pad oxide layer and a first insulating layer formed thereon;
forming a first trench with a small size and a second trench with a large size in the substrate;
forming a first dielectric layer and a second insulating layer on the first insulating layer, wherein the first trench is filled while the first dielectric layer and the second insulating layer are formed along a profile of the second trench;
patterning the second insulating layer to forming a dummy pattern in the second trench;
forming a second dielectric layer to fill the second trench and to overflow above the dummy pattern and the first dielectric layer; and
removing a portion of the second dielectric layer and a portion of the first dielectric layer to exposed the top surface of the substrate.

2. The method according to claim l, wherein a material of the first insulating layer and of the second layer comprises silicon nitride.

3. The method according to claim 1, wherein a material of the first insulating layer and of the second layer comprises silicon-oxy-nitride.

4. The method according to claim 1, wherein the first dielectric layer and the second dielectric layer comprise a silicon oxide layer.

5. The method according to claim 1, wherein the step of removing a portion of the second dielectric layer and a portion of the first dielectric layer to exposed the top surface of the substrate further comprises the steps of:
polishing a portion of the second dielectric layer and a portion of the first dielectric layer to exposed the first insulating layer; and
etching the first insulating layer and the pad oxide layer to expose the top surface of the substrate.

6. A method for forming a shallow trench isolation structure, comprising the steps of:
providing a substrate;
patterning the substrate to form a trench in the substrate;
forming a first dielectric layer on the substrate to partially cover the trench along the profile of the trench;
forming a dummy pattern on the first dielectric layer in the position of the trench;
forming a second dielectric layer to fill the trench and to overflow the dummy pattern and the first dielectric layer; and
polishing a portion of the second dielectric layer and a portion of the first dielectric layer to exposed the top surface of the substrate.

7. The method according to claim 6, wherein the dummy pattern comprises silicon nitride.

8. The method according to claim 6, wherein the dummy pattern comprises silicon-oxy-nitride.

9. The method according to claim 6, wherein the first dielectric layer and the second dielectric layer comprise a silicon oxide layer.

10. a distance between the side-wall of the photoresist layer 212 and the side-wall of the second trench 206b must be larger than 0.5 μm from a resolution criterion in photolithography.

11. A method for forming a shallow trench isolation structure, comprising the steps of:
providing a substrate having a large trench and a small trench formed therein;
forming a first dielectric layer on the substrate to fill the small trench and to fill a part of the large trench; forming a dummy pattern in the large trench; and
forming a second dielectric layer to fill the large trench other than the dummy pattern and the first dielectric layer.

12. The method according to claim 11, wherein the dummy pattern comprises silicon nitride.

13. The method according to claim 11, wherein the dummy pattern comprises silicon-oxy-nitride.

14. The method according to claim 11 wherein the first dielectric layer and the second dielectric layer comprise a silicon oxide layer.

15. The method according to claim 11, wherein a distance between the dummy pattern and the side-wall of the large trench is larger than a distance from a resolution criterion in photolithography.
